(19) United States
(12) Patent Application Publication
(10) Pub. No.: US 2014/0225231 A1
(43) Pub. Date: Aug. 14, 2014

(54) MODULATING BOW OF THIN WAFERS

(71) Applicant: INTERNATIONAL BUSINESS MACHINES CORPORATION, Armonk, NY (US)

(72) Inventors: Jeffrey P. Gambino, Westford, VT (US); John C. Hall, New Hartford, CT (US); Kenneth F. McAvey, JR., Winooski, VT (US); Charles F. Musante, Colchester, VT (US); Anthony K. Stamper, Essex Junction, VT (US)

(73) Assignee: INTERNATIONAL BUSINESS MACHINES CORPORATION, Armonk, NY (US)

(21) Appl. No.: 13/764,852

(22) Filed: Feb. 12, 2013

(51) Int. Cl. H01L 23/00; H01L 21/02

(52) U.S. Cl. CPC H01L 23/562; H01L 21/02697
USPC 257/629; 438/584

(57) ABSTRACT

Apparatus and methods modulate the bowing of thin wafers. According to a method, a wafer is formed of semiconductor material. The wafer has a front side and a back side. A cross-section of the wafer is reduced by thinning material from the front side of the wafer. A plurality of circuits comprising individual semiconductor devices are formed on the front side of the wafer. A stress-balancing layer is formed on the back side of the wafer. The stress-balancing layer comprises at least one of a polymer film and/or a metal film having at least one metal layer. A heat treatment is applied to the wafer. The heat treatment may be an annealing process to a temperature between 150° C. and 450° C., which develops an in-situ bilateral tensile stress in the stress-balancing layer that modulates the bowing of thin wafers.

### BACKGROUND

The present disclosure relates to fabrication of semiconductor devices. More particularly, the disclosure relates to methods for balancing stress in a wafer used to create semiconductor dies.

An individual integrated circuit semiconductor die is usually formed from a larger structure known as a semiconductor wafer. A wafer is a thin slice of semiconductor material, such as a silicon crystal, used in the fabrication of integrated circuits and other microdevices. The wafer serves as the substrate for microelectronic devices built in and over the wafer and undergoes many microfabrication process steps. Each semiconductor wafer typically has a plurality of integrated circuits arranged in rows and columns with the periphery of each integrated circuit being rectangular. The front side or surface of the wafer is first ground and polished to a smooth surface, for fabrication of multiple integrated circuits thereon.

Fabrication of the integrated circuits is performed on the active surface of the undivided wafer, and consists of various processes including known steps of layering, patterning, doping, etching, and heat treatment, for example. Various layers applied to the active surface of the wafer typically include insulators, semiconductors, and metallic conductors. The final layering step generally comprises the application of a passivation material to cover the integrated circuit with a smooth electrically insulative protective layer.

Wafer thinning is performed in order to (a) reduce the package size, (b) reduce the consumption of saw blades in subsequent die singulation from the wafer, and (c) remove any electrical junctions that have formed on the wafer back side during fabrication. The processes typically used for wafer thinning include mechanical grinding and chemical-mechanical polishing (CMP). Alternatively, etching may be used but is not generally preferred. Each of these processes requires protection of the front side or active surface of the wafer containing the electronic components of the semiconductor die and/or wafer.

Although wafer thinning produces semiconductor dice of much reduced size, it also tends to result in a higher incidence of semiconductor die breakage. In addition, stresses induced by any grinding and polishing processes must be carefully controlled to prevent wafer and semiconductor die warping or bowing. Wafer warp interferes with precise semiconductor die separation (singulation), and semiconductor die warping results in die-attach problems in subsequent packaging.

Stresses introduced by the passivation layer may be sufficient to produce undesirable warping in the semiconductor dice, particularly where the wafer has been thinned to a high degree.

### SUMMARY

According to an apparatus herein, a wafer comprises semiconductor material. The wafer has a front side and a back side. A plurality of circuits comprising individual semiconductor devices are formed on the front side of the wafer. A stress-balancing layer is on the back side of the wafer. The stress-balancing layer comprises either a polymeric film or a metal film having at least one metal layer. The stress-balancing layer provides an in-situ bilateral tensile stress in the stress-balancing layer as a result of a heat treatment to the wafer that modulates the bowing of thin wafers.

According to a method herein, a wafer is formed of semiconductor material. The wafer has a front side and a back side. A cross-section of the wafer is reduced by thinning material from the front side of the wafer. A plurality of circuits comprising individual semiconductor devices is formed on the front side of the wafer. A stress-balancing layer is formed on the back side of the wafer. The stress-balancing layer comprises either a polymeric film or a metal film having at least one metal layer. A heat treatment is applied to the wafer. The heat treatment develops an in-situ bilateral tensile stress in the stress-balancing layer.

According to another method herein, a wafer is formed of semiconductor material. The wafer has a front side and a back side. A cross-section of the wafer is reduced by thinning material from the front side of the wafer. A film is deposited on a back side of the wafer. A heat treatment is applied to the wafer. The heat treatment develops an in-situ bilateral tensile stress in the film.

According to another method herein, a stress-balancing layer is formed on a back side of a semiconductor wafer. The semiconductor wafer comprises a plurality of individual semiconductor circuits on a front side of the wafer. The stress-balancing layer comprises at least one of a polymer film and a metal film having at least one metal layer. The wafer is annealed to a temperature between 150° C. and 450° C.

### BRIEF DESCRIPTION OF THE DRAWINGS

The devices and methods herein will be better understood from the following detailed description with reference to the drawings, which are not necessarily drawn to scale and in which:

FIG. 1 is a cross-sectional view of a wafer illustrating the effect of process films on wafer bow;

FIG. 2 is a cross-sectional view of a wafer according to devices and methods herein;

FIG. 3 is a cross-sectional view of a wafer according to devices and methods herein;

FIG. 4 is a cross-sectional view of a wafer according to devices and methods herein;

FIG. 5 is a chart illustrating wafer bow as a function of anneal temperature; and

FIG. 6 is a flow diagram illustrating methods herein.

### DETAILED DESCRIPTION

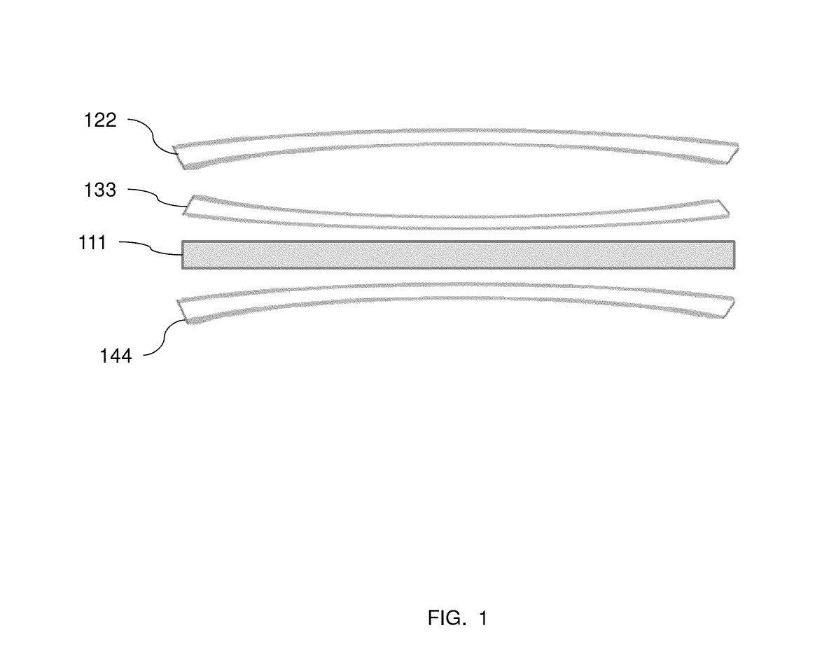

FIG. 1 is a cross-section view of a wafer 111. According to devices and methods herein, the wafer 111 may comprise a semiconductor material, such as silicon or other compositions as known in the art. The wafer 111 is subjected to a variety of stresses and strains during the manufacturing process represented by the curves in the figure. For example, the top curve 122 may represent tensile strained circuit side metal films; the next curve 133 may represent compressively strained circuit side dielectric films; and the bottom curve 144 may represent tensile strained back side metal films. As is known in the art, the wafer 111 may be subjected to many other stresses and/or strains, which, in combination, may impart a bow or other irregular shape to the wafer.

Ideally, a finished thin wafer would be perfectly flat, but process films added to the wafer tend to produce finished wafers that are significantly bowed. The actual final shape of the wafer is mostly determined by the balance of film stresses (from both front and back side films). Wafer distortion is a problem because highly bowed/warped wafers are difficult, if not impossible, to handle once they are freed from their film frames. Any amount of distortion, particularly 1 cm or more, may subsequently require that the wafer be re-attached to a film frame for wafer singulation, which is the process of cutting the wafer into separate dies. During the singulation process, a wafer with up to thousands of circuits is cut into rectangular pieces. Such handling becomes highly problematic because the probability of wafer breakage becomes unacceptably high, resulting excessive waste.

Other factors can also play a role in wafer distortion. For example, the configuration of an integrated circuit formed on the wafer affects the internal forces, particularly integrated circuit structures having a high TSV (through-silicon-via) pattern density. Devices and methods disclosed herein are particularly applicable to wafers for which the front side circuitry has been completed, and which have been substantially thinned. Thinning of the wafer may start from a thickness of approximately 750 μm and reduce the thickness to less than 150 μm.

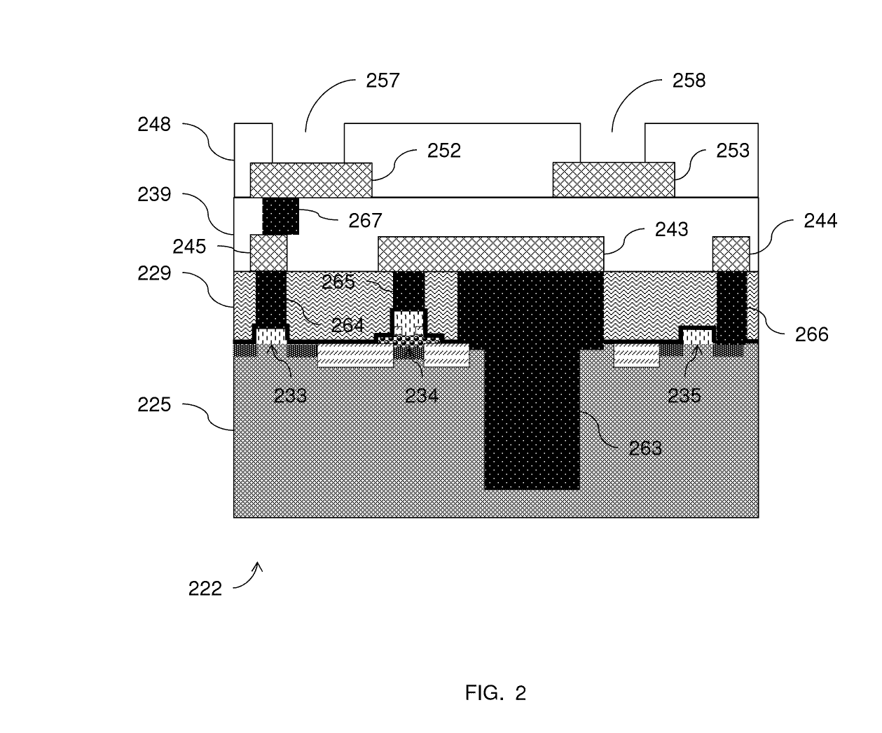

Referring to FIG. 2, a cross-sectional view of a wafer, indicated generally as 222, is shown. According to devices and methods herein, wafer 222 may comprise a multi-layer structure having a silicon layer 225; a circuit layer 229 having integrated circuit components 233, 234, 235 therein; a metallization layer 239, comprising SiO2 and one or more wires 243, 244, 245. The wafer 222 may include a second SiO2 layer 248 having metal connector pads 252, 253 and connector openings 257, 258. One or more TSVs 263, 264, 265, 266, 267 may also be included. Such TSVs may comprise tungsten or other appropriate conductor. While specific layers and materials have been described, the structure illustrated in FIG. 2 is for exemplary purposes only. Other wafer structures, as known in the art, may be used.

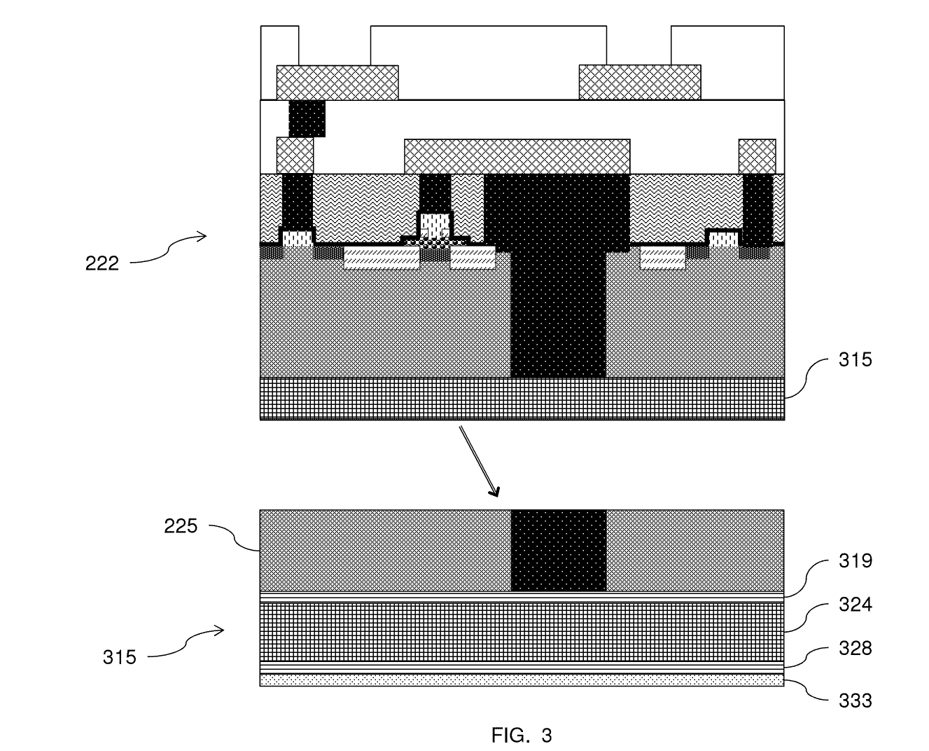

According to devices and methods herein, one method to alleviate stresses in the wafer is to grind and polish the wafer back side, apply a metal layer, and heat-treat the metal layer. Referring to FIG. 3, a stress-relieving layer 315 has been added to the back side of the wafer 222. As shown in the lower portion of the figure, the stress-relieving layer 315 may comprise one or more metal films, such as a first titanium film 319, a copper film 324, a second titanium film 328, and a gold film 333, in a multi-layer metal stack.

The material of the various layers can be polymer, metal, or a combination of polymer and metal. Materials are chosen such that when reacted, have volume shrinkage in order to enhance tensile stress. For example, a polymer film may be selected having the property that it contracts when cured and will generate a bilateral tensile stress. A metal film may be selected that is deposited with a small grain size, such as ranging from approximately 200 Angstroms to approximately 0.5 microns in mean diameter. Examples of a small grain size metal film may include an electroplated copper film or a sputtered copper film deposited on a cold chuck to suppress grain growth during deposition.

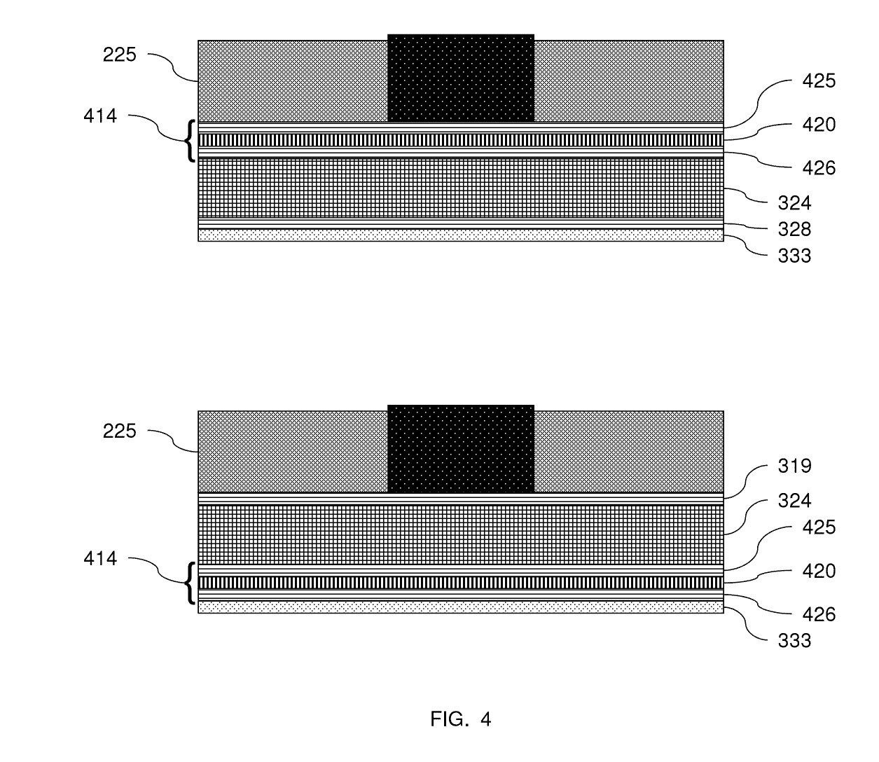

Alternatively, the stress-relieving layer 315 may comprise a “sandwich” of laminated films. The films may be formed from two dissimilar metals that react with each other and whose final volume is less than that of the reactants, individually. A metal film laminate sandwich according to devices and methods herein has two metal layers, which may include one or more layers of titanium and aluminum, such as shown in FIG. 4. In the upper portion of FIG. 4, a two-sided metal film sandwich of Ti/Al/Ti, indicated generally as 414, has an aluminum layer 420 between two titanium layers 425, 426. In the upper portion of FIG. 4, the two-sided metal film sandwich 414 is adjacent to the silicon layer 225 of the wafer 222. The copper film 324, titanium film 328, and gold film 333 are positioned below the two-sided metal film sandwich 414. In the lower portion of FIG. 4, the titanium film 319 is adjacent to the silicon layer 225 of the wafer 222. The two-sided metal film sandwich 414 is positioned between the copper film 324 and the gold film 333. It is contemplated that the metal film sandwich may comprise a multi-stack sandwich with several alternating layers of titanium and aluminum. It is further contemplated that an aluminum alloy (e.g., AlCu) can be substituted for the aluminum in the various layers. Other pairs of two dissimilar metals, such as a layer of copper and a layer of tin (Cu/Sn), can be used to form a metal film sandwich. Additionally, other materials, such as copper and silicon (Cu/Si) can be used to form a metal film sandwich. According to devices and methods herein, any binary or ternary metal for which the metal reaction is accompanied by a volume decrease can be used.

Additionally, according to devices and methods herein, the metallic stress-balancing layers can serve as a conducting element in an integrated circuit formed on the wafer. For example, the back side metal stack can be used as a conductive ground plane as well as a stress-balancing layer 315. Additionally, the same conductive film can be used with so-called insulated TSVs, which can carry power, signal, and ground lines through the back side of an integrated circuit while also serving as a stress-balancing layer.

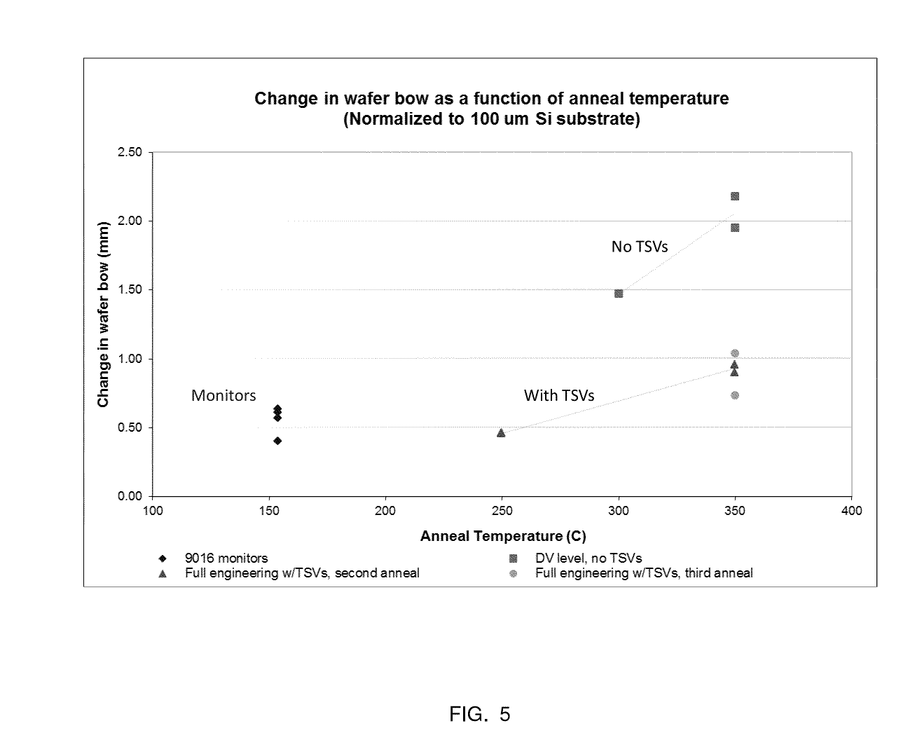

It has been determined that the final thin wafer bow can be further modulated by varying the anneal temperature of the back side metal film or film stack. FIG. 5 is a chart illustrating wafer bow as a function of anneal temperature. As shown in FIG. 5, increasing the final anneal temperature reduces the magnitude of bow of the finished wafer. A typical temperature range for back side metal anneal is 150° C.-350° C. It has been determined that increasing the final anneal temperature by a relatively small amount leads to significant changes in wafer bow, without affecting other important wafer metrics. That is, increasing the anneal temperature in a temperature range below 450° C. does not negatively affect device parametrics nor influence the function of the final product. Each type of wafer has a predictable response to annealing; moreover, changes in wafer bow are repeatable and independent of previous processing steps.

According to devices and methods herein, films that can be used to modulate the final bow of a wafer are those that undergo either grain growth or intermetallic reaction in the temperature range between 150° C. and 450° C. For example, the reaction of titanium and aluminum, as described above, will result in volume shrinkage and larger increases in tensile stress for a given set of anneal conditions.

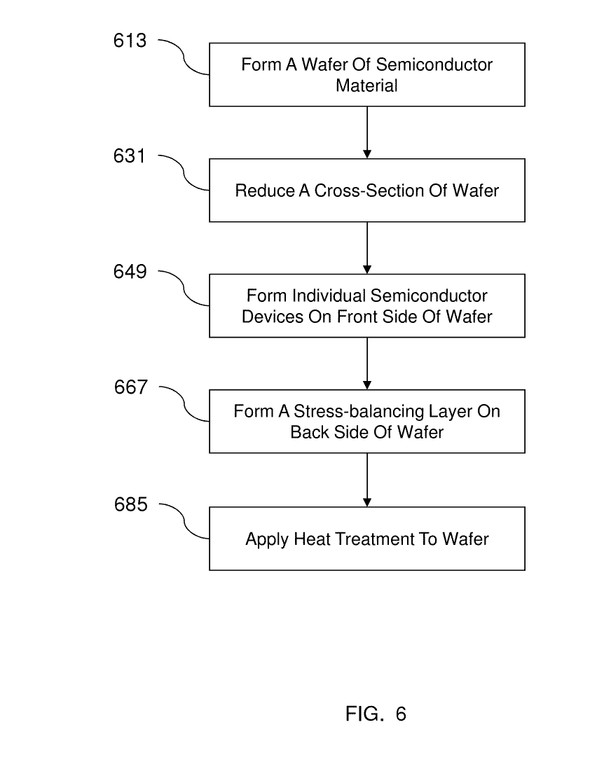

FIG. 6 is a flow diagram illustrating the processing flow of an exemplary method of modulating bow of thin wafers according to devices and methods herein. In item 613, a wafer is formed of semiconductor material. The wafer has a front side and a back side. A cross-section of the wafer is reduced by thinning material from the front side of the wafer, at 631. In item 649, a plurality of circuits comprising individual semiconductor devices is formed on the front side of the wafer. In item 667, a stress-balancing layer is formed on the back side of the wafer. The stress-balancing layer comprises at least one of a polymer film and/or a metal film having at least one metal layer. In item 685, a heat treatment is applied to the wafer. The heat treatment may be an annealing process to a temperature between 150° C. and 450° C., which develops an in-situ bilateral tensile stress in the stress-balancing layer.

In summary, methods herein reduce warpage of a wafer by depositing a special film, or combination of special films, on the wafer back side and applying a heat treatment that causes the special films to develop an in-situ bilateral tensile stress. Such heat treatment is controlled (adjusted) by varying the anneal temperature to modulate the amount that the thin wafer bows. Therefore, by controlling the anneal temperature; the bow of such thin wafers can be modulated (or even eliminated). Further, the different layers within the laminated stress-balancing layer react to bond with each other during the annealing process to develop a permanent in-situ bilateral tensile stress in the stress-balancing layer that remains after the annealing process is completed (remains in the final product).

The method as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

For electronic applications, semiconducting substrates, such as silicon wafers, can be used. The substrate enables easy handling of the micro device through the many fabrication steps. Often, many individual devices are made together on one substrate and then singulated into separated devices toward the end of fabrication. In order to fabricate a microdevice, many processes are performed, one after the other, many times repeatedly. These processes typically include depositing a film, patterning the film with the desired micro features, and removing (or etching) portions of the film. For example, in memory chip fabrication, there may be several lithography steps, oxidation steps, etching steps, doping steps, and many others are performed. The complexity of microfabrication processes can be described by their mask count.

Flip chip is a method for interconnecting semiconductor devices, such as IC chips, to external circuitry with solder bumps that have been deposited onto the chip pads. The solder bumps are deposited on the chip pads on the top side of the wafer during the final wafer processing step. In order to mount the chip to external circuitry (e.g., a circuit board or another chip or wafer), it is flipped over so that its top side faces down, and aligned so that its pads align with matching pads on the external circuit, and then the solder is flowed to complete the interconnect. This is in contrast to wire bonding, in which the chip is mounted upright, and wires are used to interconnect the chip pads to external circuitry.

For purposes herein, a “semiconductor” is a material or structure that may include an implanted impurity that allows the material to sometimes be a conductor and sometimes be an insulator, based on electron and hole carrier concentration. As used herein, “implantation processes” can take any appropriate form (whether now known or developed in the future) and can comprise, for example, ion implantation, etc.

The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as tungsten, hafnium, tantalum, molybdenum, titanium, or nickel, or a metal silicide, any alloys of such metals, and may be deposited using physical vapor deposition, chemical vapor deposition, or any other technique known in the art.

When patterning any material herein, the material to be patterned can be grown or deposited in any known manner and a patterning layer (such as an organic photoresist) can be formed over the material. The patterning layer (resist) can be exposed to some pattern of light radiation (e.g., patterned exposure, laser exposure, etc.) provided in a light exposure pattern, and then the resist is developed using a chemical agent. This process changes the physical characteristics of the portion of the resist that was exposed to the light. Then one portion of the resist can be rinsed off, leaving the other portion of the resist to protect the material to be patterned. A material removal process is then performed (e.g., plasma etching, etc.) to remove the unprotected portions of the material to be patterned. The resist is subsequently removed to leave the underlying material patterned according to the light exposure pattern.

A hardmask can be formed of any suitable material, whether now known or developed in the future, such as a metal or organic hardmask, that has a hardness greater than the substrate and insulator materials used in the remainder of the structure.

The terminology used herein is for the purpose of describing particular devices and methods only and is not intended to be limiting of this disclosure. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements).

The corresponding structures, materials, acts, and equivalents of all means or step plus function elements in the claims below are intended to include any structure, material, or act for performing the function in combination with other claimed elements as specifically claimed. The descriptions of the various devices and methods of the present disclosure have been presented for purposes of illustration, but are not intended to be exhaustive or limited to the devices and methods disclosed. Many modifications and variations will be apparent to those of ordinary skill in the art without departing from the scope and spirit of the described devices and methods. The terminology used herein was chosen to best explain the principles of the devices and methods, the practical application or technical improvement over technologies found in the marketplace, or to enable others of ordinary skill in the art to understand the devices and methods disclosed herein.

What is claimed is:

1. An apparatus, comprising:
a wafer comprising semiconductor material, said wafer having a front side and a back side, a plurality of circuits comprising individual semiconductor devices being formed on said front side of said wafer; and
a stress-balancing layer on said back side of said wafer,
said stress-balancing layer comprising at least one of a polymer film and a metal film having at least one metal layer,
said stress-balancing layer comprising a heat-treated layer, being subjected to a heat treatment,
said stress-balancing layer having an in-situ bilateral tensile stress resulting from said heat treatment.

2. The apparatus according to claim 1, said metal film comprising a metal film laminate comprising two metal layers selected from two dissimilar metals, said two dissimilar metals reacting to produce a volume decrease.

3. The apparatus according to claim 2, said two dissimilar metals comprising titanium and one of aluminum and aluminum alloy.

4. The apparatus according to claim 2, said two dissimilar metals comprising copper and tin.

5. The apparatus according to claim 2, said metal film laminate comprising a layer of copper and a layer of silicon.

6. The apparatus according to claim 1, said stress-balancing layer further comprising a first titanium film, a copper film, a second titanium film, and a gold film, in a multi-layer metal stack.

7. The apparatus according to claim 1, said heat treatment comprising annealing said wafer to a temperature between 150° C. and 450° C.

8. A method, comprising:
forming a wafer of semiconductor material, said wafer having a front side and a back side;
reducing a cross-section of said wafer by thinning material from said front side of said wafer;
forming a plurality of circuits comprising individual semiconductor devices on said front side of said wafer;
forming a stress-balancing layer on said back side of said wafer, said stress-balancing layer comprising at least one of a polymer film and a metal film having at least one metal layer; and
applying a heat treatment to said wafer, said heat treatment developing an in-situ bilateral tensile stress in said stress-balancing layer.

9. The method according to claim 8, said metal film comprising a metal film laminate comprising two metal layers selected from two dissimilar metals, said two dissimilar metals reacting to produce a volume decrease.

10. The method according to claim 9, said two dissimilar metals comprising titanium and one of aluminum and aluminum alloy.

11. The method according to claim 9, said two dissimilar metals comprising copper and tin.

12. The method according to claim 9, said metal film laminate comprising a layer of copper and a layer of silicon.

13. The method according to claim 8, said stress-balancing layer further comprising a first titanium film, a copper film, a second titanium film, and a gold film, in a multi-layer metal stack.

14. The method according to claim 8, said heat treatment to said wafer comprising annealing said wafer to a temperature between 150° C. and 450° C.

15. A method, comprising:
forming a wafer of semiconductor material, said wafer having a front side and a back side;
reducing a cross-section of said wafer by thinning material from said front side of said wafer;
depositing a film on a back side of said wafer; and
applying a heat treatment to said wafer, said heat treatment developing an in-situ bilateral tensile stress in said film.

16. The method according to claim 15, said film comprising at least one of a polymer film and a metal film having at least one metal layer.

17. The method according to claim 16, said metal film comprising a metal film laminate comprising two metal layers selected from two dissimilar metals, said two dissimilar metals reacting to produce a volume decrease.

18. The method according to claim 17, said two dissimilar metals being selected from the group consisting of:
titanium and one of aluminum and aluminum alloy; and
copper and tin.

19. The method according to claim 17, said metal film laminate comprising a layer of copper and a layer of silicon.

20. The method according to claim 15, said heat treatment to said wafer comprising annealing said wafer to a temperature between 150° C. and 450° C.

21. A method, comprising:
forming a stress-balancing layer on a back side of a semiconductor wafer,
said semiconductor wafer comprising a plurality of individual semiconductor circuits on a front side of said wafer, and
said stress-balancing layer comprising at least one of a polymer film and a metal film having at least one metal layer; and
annealing said wafer to a temperature between 150° C. and 450° C.

22. The method according to claim 21, said metal film comprising a metal film laminate comprising two metal layers selected from two dissimilar metals, said two dissimilar metals reacting to produce a volume decrease.

23. The method according to claim 22, said two dissimilar metals being selected from the group consisting of:
titanium and one of aluminum and aluminum alloy; and
copper and tin.

24. The method according to claim 22, said metal film laminate comprising a layer of copper and a layer of silicon.

25. The method according to claim 21, said stress-balancing layer further comprising a first titanium film, a copper film, a second titanium film, and a gold film, in a multi-layer metal stack.
